(19) United States
(12) Patent Application Publication
(10) Pub. No.: US 2025/0316547 A1
(43) Pub. Date: Oct. 9, 2025

(54) DIE STRUCTURES AND METHODS OF FORMING THE SAME

(71) Applicant: Taiwan Semiconductor Manufacturing Co., Ltd., Hsinchu (TW)

(72) Inventors: Hsien-Wei Chen, Hsinchu (TW); Shin-Puu Jeng, Hsinchu (TW)

(21) Appl. No.: 19/243,312

(22) Filed: Jun. 19, 2025

Related U.S. Application Data
(63) Continuation of application No. 18/476,591, filed on Sep. 28, 2023.
(60) Provisional application No. 63/507,197, filed on Jun. 9, 2023.

(51) Int. Cl. H01L 23/31; H01L 21/56; H01L 21/683; H01L 23/00

(52) U.S. Cl. CPC H01L 23/3107; H01L 21/565; H01L 21/6835; H01L 24/05; H01L 24/08; H01L 24/16; H01L 24/73; H01L 24/81; H01L 2221/68327; H01L 2224/0401; H01L 2224/05569; H01L 2224/08145; H01L 2224/80895; H01L 2224/80948; H01L 2224/81815; H01L 2924/35121

(57) ABSTRACT

Various embodiments include die structures and methods of forming die structures. In an embodiment, a device includes: a lower substrate; upper integrated circuit dies bonded to the lower substrate with dielectric-to-dielectric bonds and with metal-to-metal bonds, the upper integrated circuit dies including a semiconductor material; a buffer layer around the upper integrated circuit dies, the buffer layer including a stress reduction compound, a coefficient of thermal expansion of the stress reduction compound being greater than a coefficient of thermal expansion of the semiconductor material; and an encapsulant around the buffer layer and the upper integrated circuit dies, the encapsulant including a molding compound, a coefficient of thermal expansion of the molding compound being greater than the coefficient of thermal expansion of the stress reduction compound.

### PRIORITY CLAIM AND CROSS-REFERENCE

This application is a continuation of U.S. patent application Ser. No. 18/476,591, filed on Sep. 28, 2023, entitled “Die Structures and Methods of Forming the Same,” which claims the benefit of U.S. Provisional Application No. 63/507,197, filed on Jun. 9, 2023, which applications are hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an integrated circuit die.

FIGS. 2-11 are views of intermediate stages in the manufacturing of die structures, in accordance with some embodiments.

FIG. 12 is a cross-sectional view of a die structure, in accordance with some other embodiments.

FIG. 13 is a cross-sectional view of a die structure, in accordance with some other embodiments.

FIG. 14 is a cross-sectional view of a die structure, in accordance with some other embodiments.

FIG. 15 is a cross-sectional view of a die structure, in accordance with some other embodiments.

FIG. 16 is a planar view of a die structure, in accordance with some embodiments.

FIGS. 17 and 18 are views of a die structure, in accordance with some other embodiments.

FIG. 19 is a cross-sectional view of a die structure, in accordance with some other embodiments.

FIG. 20 is a cross-sectional view of an integrated circuit package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, die structures each include a lower substrate, upper integrated circuit dies bonded to the lower substrate, and one or more buffer layer(s) around the upper integrated circuit dies. An encapsulant is around the buffer layer(s) and the upper integrated circuit dies. The buffer layer(s) are formed of a stress reduction compound that may help reduce stress exerted on the bonding interfaces of the upper integrated circuit dies and the lower substrate during expansion of the encapsulant at high temperatures. The yield and reliability of the die structures may thus be improved.

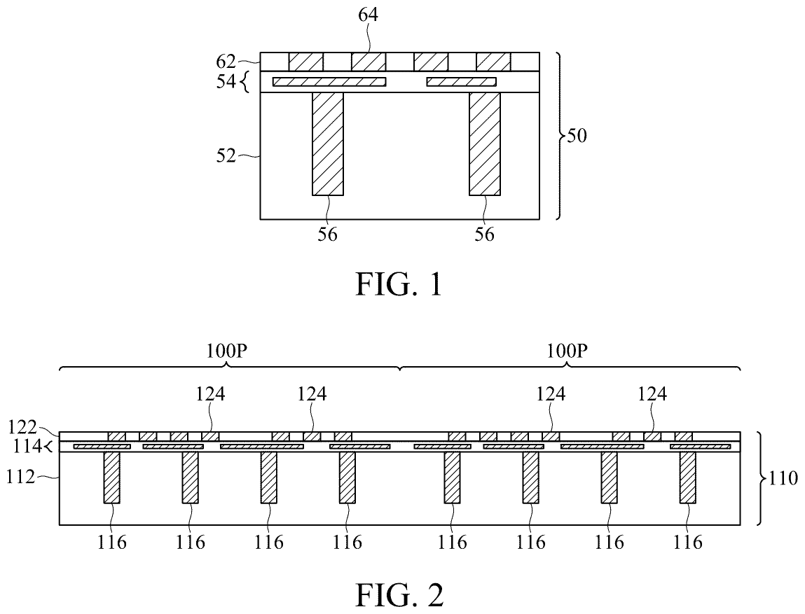

FIG. 1 is a cross-sectional view of an integrated circuit die 50. The integrated circuit die 50 will be bonded to other dies in subsequent processing to form a die structure. The integrated circuit die 50 may be a logic die (e.g., central processing unit (CPU), graphics processing unit (GPU), system-on-a-chip (SoC) die, application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, an interface die, a sensor die, a micro-electro-mechanical-system (MEMS) die, a signal processing die (e.g., digital signal processing (DSP) die), a front-end die (e.g., analog front-end (AFE) dies), the like, or combinations thereof.

The integrated circuit die 50 may be formed in a wafer, which may include different device regions that are singulated to form a plurality of integrated circuit dies. The integrated circuit die 50 may be processed according to applicable manufacturing processes to form integrated circuits. For example, the integrated circuit die 50 includes a semiconductor substrate 52, which may be a substrate of silicon, doped or undoped, or an active layer of a semiconductor-on-insulator (SOI) substrate. The semiconductor substrate 52 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The semiconductor substrate 52 has an active surface (e.g., the surface facing upward in FIG. 1) and an inactive surface (e.g., the surface facing downward in FIG. 1). Devices (not separately illustrated) may be formed in and/or on the active surface of the semiconductor substrate 52. The devices may be active devices (e.g., transistors, diodes, etc.) and/or passive devices (e.g., capacitors, inductors, resistors, etc.). The inactive surface may be free from devices.

An interconnect structure 54 is disposed over the active surface of the semiconductor substrate 52, and is used to electrically connect the devices of the semiconductor substrate 52 to form an integrated circuit. The interconnect structure 54 may include one or more dielectric layer(s) and respective metallization layer(s) in the dielectric layer(s). The dielectric layer(s) may be, e.g., low-k dielectric layer(s). The metallization layer(s) may include conductive vias and/or conductive lines to interconnect the devices of the semiconductor substrate 52. The metallization layer(s) may be formed of a conductive material, such as a metal, such as copper, cobalt, aluminum, gold, combinations thereof, or the like. The metallization layer(s) of the interconnect structure 54 may be formed by a damascene process, such as a single damascene process, a dual damascene process, or the like.

Optionally, conductive vias 56 extend into the interconnect structure 54 and/or the semiconductor substrate 52. The conductive vias 56 are electrically coupled to the metallization layer(s) of the interconnect structure 54. As an example to form the conductive vias 56, recesses can be formed in the interconnect structure 54 and/or the semiconductor substrate 52 by, for example, etching, milling, laser techniques, a combination thereof, or the like. A thin barrier layer may be conformally deposited in the recesses, such as by chemical vapor deposition (CVD), atomic layer deposition (ALD), physical vapor deposition (PVD), thermal oxidation, a combination thereof, or the like. The barrier layer may be formed of an oxide, a nitride, combinations thereof, or the like. A conductive material may be formed over the barrier layer and in the recesses. The conductive material may be formed by an electro-chemical plating process, CVD, ALD, PVD, a combination thereof, or the like. Examples of conductive materials include copper, tungsten, aluminum, silver, gold, a combination thereof, or the like. Excess conductive material and barrier layer is removed from a surface of the interconnect structure 54 or the semiconductor substrate 52 by, for example, a chemical-mechanical polish (CMP). The remaining portions of the barrier layer and conductive material in the recesses form the conductive vias 56. After their initial formation, the conductive vias 56 may be buried in the semiconductor substrate 52. The semiconductor substrate 52 may be thinned in subsequent processing to expose the conductive vias 56 at the inactive surface of the semiconductor substrate 52. After the exposure process, the conductive vias 56 are through-substrate vias (TSVs), such as through-silicon vias, that extend through the semiconductor substrate 52.

A dielectric layer 62 is over the interconnect structure 54, at the front-side of the integrated circuit die 50. The dielectric layer 62 may be formed of an oxide such as silicon oxide, phosphosilicate glass (PSG), borosilicate glass (BSG), boron-doped phosphosilicate glass (BPSG), a tetraethyl orthosilicate (TEOS) based oxide, or the like; a nitride such as silicon nitride or the like; a polymer such as polybenzoxazole (PBO), polyimide, a benzocyclobutene (BCB) based polymer, or the like; a combination thereof; or the like. The dielectric layer 62 may be formed, for example, by CVD, spin coating, lamination, or the like. Optionally, one or more passivation layer(s) (not separately illustrated) are disposed between the dielectric layer 62 and the interconnect structure 54.

Die connectors 64 extend through the dielectric layer 62. The die connectors 64 may include conductive pillars, pads, or the like, to which external connections can be made. In some embodiments, the die connectors 64 include bond pads at the front-side of the integrated circuit die 50, and include bond pad vias that connect the bond pads to an upper metallization layer of the interconnect structure 54. In such embodiments, the die connectors 64 (including the bond pads and the bond pad vias) may be formed by a damascene process, such as a single damascene process, a dual damascene process, or the like. The die connectors 64 may be formed of a suitable conductive material, such as copper, tungsten, aluminum, silver, gold, a combination thereof, or the like, which can be formed by, for example, plating or the like.

Optionally, solder regions (not separately illustrated) may be disposed on the die connectors 64 during formation of the integrated circuit die 50. The solder regions may be used to perform chip probe (CP) testing on the integrated circuit die 50. For example, the solder regions may be solder balls, solder bumps, or the like, which are used to attach a chip probe to the die connectors 64. Chip probe testing may be performed on the integrated circuit die 50 to ascertain whether the integrated circuit die 50 is a known good die (KGD). Thus, only integrated circuit dies 50, which are KGDs, undergo subsequent processing are packaged, and dies which fail the chip probe testing are not packaged. After testing, the solder regions may be removed. In some embodiments, a planarization process such as a chemical mechanical polish (CMP), an etch-back process, combinations thereof, or the like is utilized.

FIGS. 2-11 are views of intermediate stages in the manufacturing of die structures 100 (see FIG. 11), in accordance with some embodiments. FIGS. 2, 3, 4, 5, 6, 7, 8, 9, 10, and 11 are cross-sectional views. The die structures 100 are stacks of integrated circuit dies. The die structures 100 are formed by bonding integrated circuit dies 50 to a wafer 110. The wafer 110 has package regions 100P, which include devices (e.g., integrated circuit dies, interposers, etc.) formed therein. The package regions 100P will be singulated to form die structures 100 that each include a singulated portion of the wafer 110 (e.g., an integrated circuit die, interposer, or the like) and the integrated circuit dies 50 that are bonded to the singulated portion of the wafer 110.

A die structure 100 (see FIG. 11) is a component that may be subsequently packaged to form an integrated circuit package. The integrated circuit dies of the die structure 100 may be heterogeneous dies. Packaging the die structure 100 in lieu of packaging the dies individually may allow heterogeneous dies to be integrated with a small footprint. The die structure 100 may be a system-on-integrated-chips (SoIC) device, although other types of devices may be formed.

In FIG. 2, a wafer 110 is formed or obtained. The wafer 110 includes devices in corresponding package regions 100P, which will be singulated in subsequent processing to be included in the die structures 100. The devices formed in the wafer 110 may be integrated circuit dies, interposers, or the like.

The wafer 110 may be processed according to applicable manufacturing processes to form devices. For example, the wafer 110 includes a substrate 112, an interconnect structure 114, conductive vias 116, a dielectric layer 122, and die connectors 124, which may be similar to, respectively, the semiconductor substrate 52, the interconnect structure 54, the conductive vias 56, the dielectric layer 62, and the die connectors 64 (previously described for FIG. 1). In embodiments where integrated circuits devices are formed in the wafer 110, active devices (and optionally, passive devices) may be formed in and/or on an active surface (e.g., the surface facing upward in FIG. 2) of the substrate 112. In embodiments where interposers are formed in the wafer 110, the substrate 112 generally does not include active devices, although the interposers may include passive devices formed in and/or on an active surface of the substrate 112. The dielectric layer 122 and the die connectors 124 may be disposed at the front-side of the wafer 110.

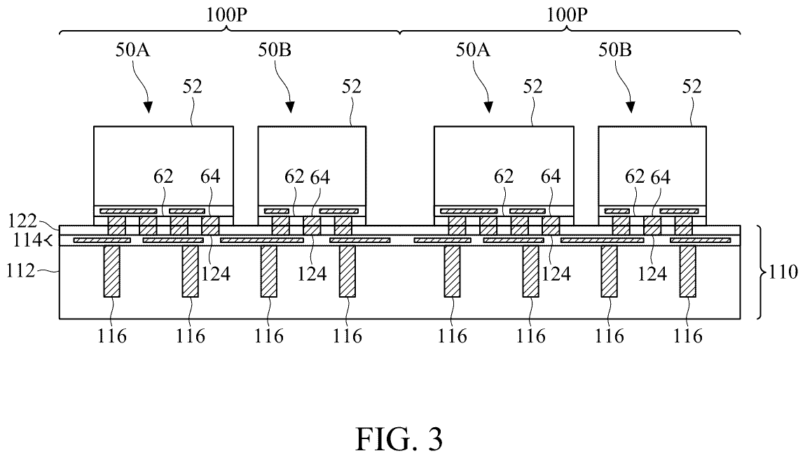

In FIG. 3, integrated circuit dies 50 are bonded to the wafer 110. In this embodiment, the integrated circuit dies 50 include multiple integrated circuit dies 50A, 50B that are placed in each of the package regions 100P. The integrated circuit dies 50A, 50B may each have a single function (e.g., a logic device, memory device, etc.), or may have multiple functions (e.g., a SoC). In an embodiment, the integrated circuit dies 50A are logic dies and the integrated circuit dies 50B are memory dies. In this embodiment, an integrated circuit die 50A (e.g., a logic device) and an integrated circuit die 50B (e.g., a memory device) are bonded in each of the package regions 100P. The interconnect structure 114 may interconnect the integrated circuit dies 50 in a package region 100P to form a functional system. In another embodiment, a single integrated circuit die 50 is bonded in each of the package regions 100P.

The integrated circuit dies 50 are directly bonded to the wafer 110. In this embodiment, the integrated circuit dies 50 and the wafer 110 are directly bonded in a face-to-face manner, such that the front-sides of the integrated circuit dies 50 are bonded to the front-side of the wafer 110. The integrated circuit dies 50 may be bonded to the wafer 110 by hybrid bonding. In hybrid bonding, the dielectric layers 62 of the integrated circuit dies 50 are bonded to the dielectric layer 122 of the wafer 110 through dielectric-to-dielectric bonding, without using any adhesive material (e.g., die attach film), and the die connectors 64 of the integrated circuit dies 50 are bonded to the die connectors 124 of the wafer 110 through metal-to-metal bonding, without using any eutectic material (e.g., solder). The bonding may include a pre-bonding and an annealing. During the pre-bonding, a small pressing force is applied to press the integrated circuit dies 50 against the wafer 110. The pre-bonding is performed at a low temperature, such as room temperature, and after the pre-bonding, the dielectric layers 62 are bonded to the dielectric layer 122. The bonding strength is then improved in a subsequent annealing step, in which the dielectric layers 62, 122 are annealed at a high temperature, such as a temperature in the range of about 150° C. to about 300° C. The annealing forms bonds, such as fusions bonds, that bond the dielectric layers 62 to the dielectric layer 122. For example, the bonds can be covalent bonds between the material of the dielectric layers 62 and the material of the dielectric layer 122. The die connectors 64 are connected to the die connectors 124 with a one-to-one correspondence. The die connectors 64 may be in physical contact with the die connectors 124 after the pre-bonding, or may expand to be brought into physical contact during the annealing. Further, during the annealing, the material of the die connectors 64, 124 (e.g., copper) intermingles, so that metal-to-metal bonds are also formed. Hence, the resulting bonds between the integrated circuit dies 50 and the wafer 110 include both dielectric-to-dielectric bonds and metal-to-metal bonds.

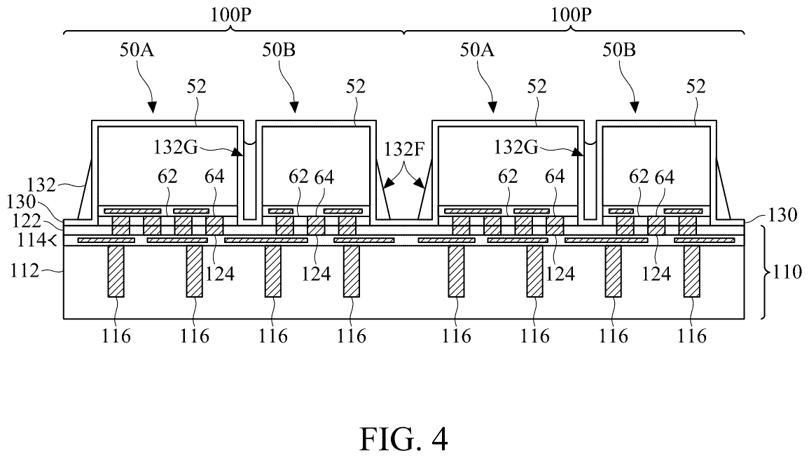

In FIG. 4, buffer layers 132 are dispensed around the integrated circuit dies 50 and on the front-side of the wafer 110. In this embodiment, a buffer layer 132 is dispensed around the integrated circuit dies 50 in each of the package regions 100P. As subsequently described in greater detail, the integrated circuit dies 50 will be encapsulated. An encapsulant has a large coefficient of thermal expansion (CTE) as compared to that of the integrated circuit dies 50, such that there may be a CTE mismatch between the encapsulant and the integrated circuit dies 50. The buffer layers 132 are formed adjacent the bonding interfaces of the integrated circuit dies 50 and the wafer 110, such that the buffer layers 132 will be between the integrated circuit dies 50 and the subsequently formed encapsulant. The buffer layers 132 may reduce stress exerted on the bonding interfaces of the integrated circuit dies 50 and the wafer 110 as a result of CTE mismatch. The risk of the dielectric layers 62, 122 delaminating may thus be reduced, thereby improving the yield and reliability of the die structures 100.

The buffer layers 132 are formed of a stress reduction compound that helps reduce stress exerted on the bonding interfaces of the integrated circuit dies 50 and the wafer 110. The stress reduction compound includes a polymer material and optionally includes a filler. The polymer material may be a polyester, a polyamide, a polycarbonate, a polyurethane, or the like. For example, the polymer material may be a thermoplastic polymer such as polyethylene terephthalate. The filler is formed of a material that provides mechanical strength for the buffer layers 132, such as particles of silica (SiO₂). The stress reduction compound may be applied in liquid or semi-liquid form by deposition (e.g., CVD), capillary flow, lamination, or the like, and then subsequently cured.

The buffer layers 132 may have fillet portions 132F and gap portions 132G. The gap portions 132G are disposed in the gaps between the integrated circuit dies 50 within the respective package regions 100P. The fillet portions 132F are disposed along the outer edges of the integrated circuit dies 50 within the respective package regions 100P, and include fillets.

A liner layer 130 may be formed between the buffer layers 132 and the integrated circuit dies 50 and the wafer 110. The liner layer 130 may protect the various components from moisture that is released during a subsequent encapsulation process, which may increase the reliability of the die structures 100. The liner layer 130 may be formed of a dielectric material such as a nitride (e.g., silicon nitride), an oxide (e.g., silicon oxide), combinations thereof (e.g., silicon oxynitride), multi-layers thereof, or the like, which may be formed by a suitable deposition method such as ALD, CVD, or the like. The dielectric material may be inorganic. In some embodiments, the liner layer 130 includes an oxide layer and a nitride layer over the oxide layer, which may be advantageous when the nitride layer has a large hardness. In some embodiments, the liner layer 130 has a thickness in the range of 0.2 μm to 0.4 μm.

In this embodiment, the buffer layers 132 are formed on the liner layer 130. Thus, the liner layer 130 physically contacts the sidewalls of the integrated circuit dies 50 and the top surface of the wafer 110, while the buffer layers 132 physically contacts the sidewalls and top surfaces of the liner layer 130. The liner layer 130 is optional. In another embodiment (subsequently described for FIG. 12), the liner layer 130 is omitted and the buffer layers 132 are formed directly on the integrated circuit dies 50 and the wafer 110.

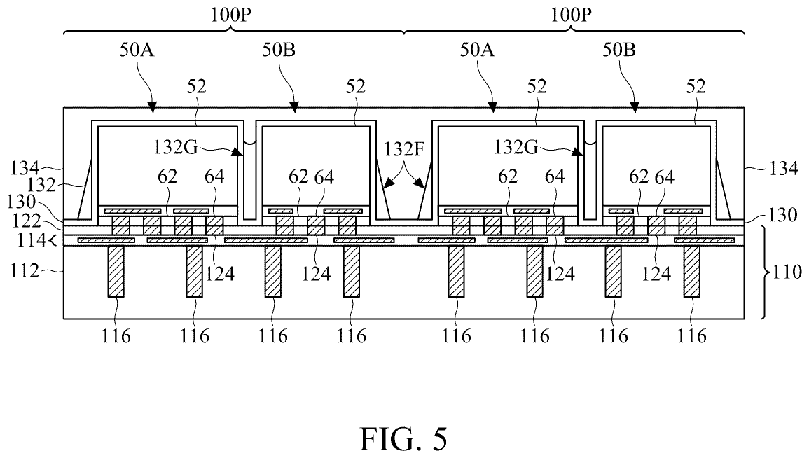

In FIG. 5, an encapsulant 134 is formed on and around the various components. After formation, the encapsulant 134 encapsulates the integrated circuit dies 50, the liner layer 130 (if present), and the buffer layers 132. The encapsulant 134 may be formed of a molding compound, which may be applied by compression molding, transfer molding, or the like. The molding compound may include an organic material. The molding compound of the encapsulant 134 is different from the stress reduction compound of the buffer layers 132, and may be formed by a different method than the stress reduction compound of the buffer layers 132. The molding compound may be applied in liquid or semi-liquid form and then subsequently cured. The encapsulant 134 may be formed over the wafer 110 such that the liner layer 130 (if present), the buffer layers 132, and/or the integrated circuit dies 50 are buried or covered.

The CTE of the integrated circuit dies 50 may be largely determined by the CTE of the semiconductor substrates 52, which are formed of a semiconductor material. The encapsulant 134 surrounds and protects the integrated circuit dies 50. However, the molding compound of the encapsulant 134 has a large CTE as compared to the semiconductor material of the integrated circuit dies 50. As a result, the encapsulant 134 may expand more than the integrated circuit dies 50 at high temperatures. Expansion of the encapsulant 134 at high temperatures can exert stress on the bonding interfaces of the integrated circuit dies 50 and the wafer 110. The buffer layers 132 are formed of a stress reduction compound that may reduce stress exerted on those bonding interfaces as a result of CTE mismatch. Specifically, the CTE of the stress reduction compound of the buffer layers 132 is between the CTE of the molding compound of the encapsulant 134 and the CTE of the semiconductor material of the integrated circuit dies 50. In other words, the CTE of the stress reduction compound of the buffer layers 132 is greater than the CTE of the semiconductor material of the integrated circuit dies 50, while the CTE of the molding compound of the encapsulant 134 is greater than the CTE of the stress reduction compound of the buffer layers 132. In some embodiments, the semiconductor material of the integrated circuit dies 50 has a CTE in the range of 2 ppm/° C. to 3 ppm/° C., the stress reduction compound of the buffer layers 132 has a CTE in the range of 5 ppm/° C. to 20 ppm/° C., and the molding compound of the encapsulant 134 has a CTE in the range of 30 ppm/° C. to 40 ppm/° C. Thus, the buffer layers 132 may reduce stress caused by a CTE mismatch between the encapsulant 134 and the integrated circuit dies 50, which may reduce the risk of the dielectric layers 62, 122 delaminating (specifically, at the edges of the integrated circuit dies 50). The yield and reliability of the die structures 100 may thus be improved.

As previously noted, the stress reduction compound of the buffer layers 132 optionally includes a filler. When a filler is used, the CTE of the stress reduction compound may be tuned to a desired amount by controlling the filler type (e.g., material), filler load (e.g., quantity of filler), and/or average filler particle size. In some embodiments where the stress reduction compound of the buffer layers 132 includes a filler, the filler is particles of silica having a load in the range of 60% to 90% and having an average particle size in the range of 5 μm to 30 μm. Thus, the stress reduction compound may be formed with a desired CTE (previously described).

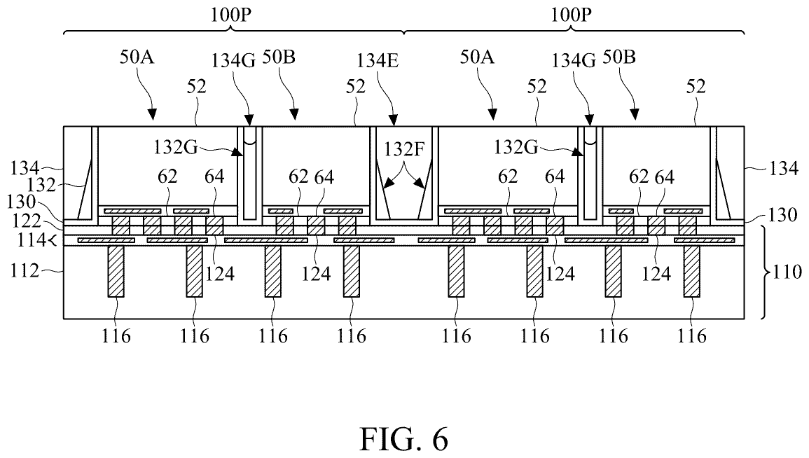

In FIG. 6, a removal process is (optionally) performed on the encapsulant 134 to expose the integrated circuit dies 50. The removal process may remove portions of the liner layer 130 (if present), the buffer layers 132, and/or the integrated circuit dies 50 until the integrated circuit dies 50 are exposed. In some embodiments, a planarization process such as a chemical mechanical polish (CMP), a grinding process, or the like may be utilized. The top surfaces of the integrated circuit dies 50, the encapsulant 134, the liner layer 130 (if present), and optionally the buffer layers 132 are substantially coplanar (within process variations) after the planarization process. The removal process may be omitted, for example, if the integrated circuit dies 50 are already exposed.

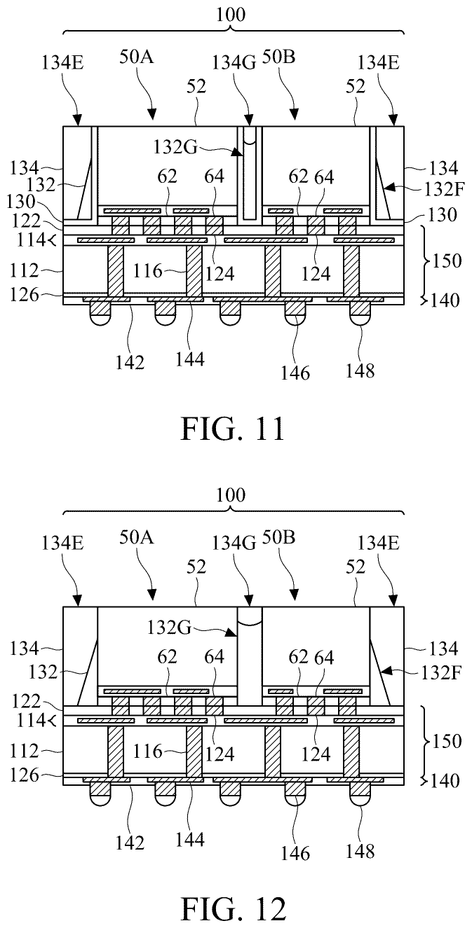

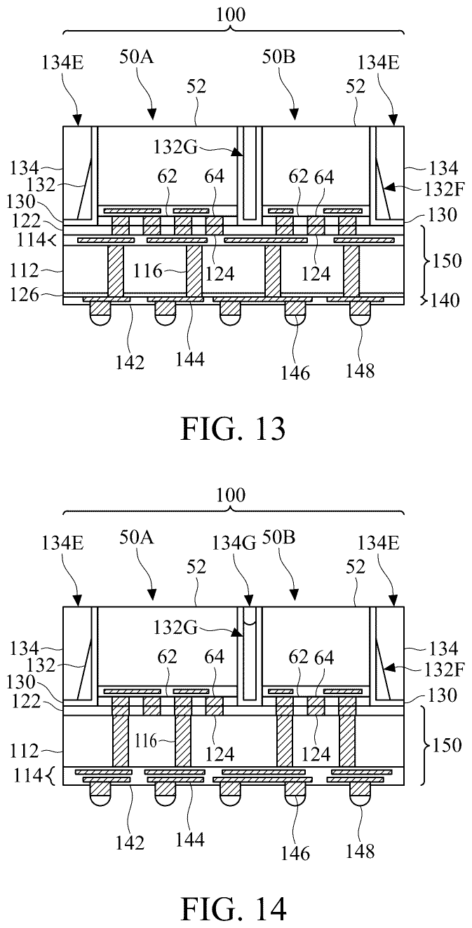

The encapsulant 134 may have edge portions 134E and gap portions 134G. The gap portions 134G are disposed in the gaps between the integrated circuit dies 50 within the respective package regions 100P, e.g., over the gap portions 132G of the buffer layers 132. The edge portions 134E are disposed along the outer edges of the integrated circuit dies 50 within the respective package regions 100P, e.g., over the fillet portions 132F of the buffer layers 132. In some embodiments, the gap portions 134G of the encapsulant 134 remaining after the removal process have a thickness in the range of 0 μm to 40 μm. More generally, the gap portions 134G of the encapsulant 134 may (or may not) remain after the removal process. In this embodiment, the gap portions 134G of the encapsulant 134 remain after the removal process. Thus, the gap portions 132G of the buffer layers 132 are below the top surface of the encapsulant 134. In another embodiment (subsequently described for FIG. 13), the gap portions 134G of the encapsulant 134 are removed by the removal process.

The liner layer 130 (if present) and the integrated circuit dies 50 are exposed through the encapsulant 134 while the fillet portions 132F of the buffer layers 132 remain covered by the encapsulant 134. Thus, the thickness of the encapsulant 134 is greater than the thickness of the fillet portions 132F of the buffer layers 132. In some embodiments, the thickness of the encapsulant 134 is in the range of 300 μm to 500 μm, such as about 400 μm, while the thickness of the fillet portions 132F of the buffer layers 132 is in the range of 210 μm to 350 μm, such as about 280 μm. The thickness of the fillet portions 132F of the buffer layers 132 may be at least half the thickness of the encapsulant 134. Additionally, the thickness of the gap portions 132G of the buffer layer 132 may (or may not) be greater than the thickness of the fillet portions 132F of the buffer layer 132. The thicknesses of the buffer layers 132 and the encapsulant 134 are measured in a direction that is perpendicular to a major surface of the wafer 110.

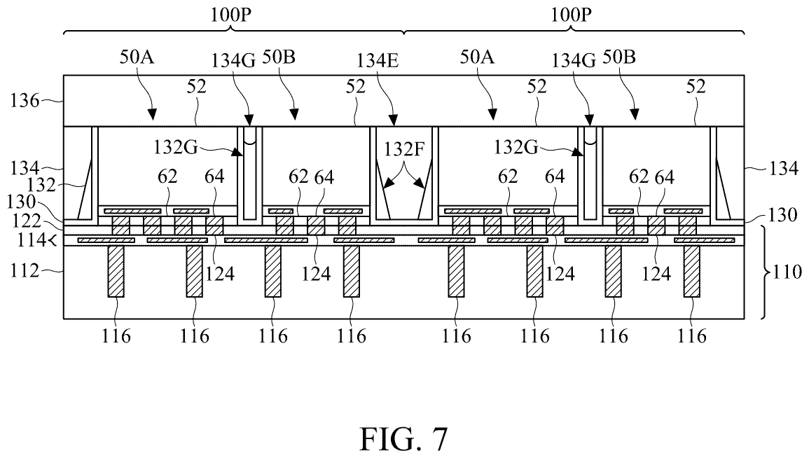

In FIG. 7, the wafer 110 is placed on a carrier substrate 136 or other suitable support structure for subsequent processing. In some embodiments, the carrier substrate 136 is a bulk semiconductor or a glass substrate. The carrier substrate 136 is attached to at least the encapsulant 134. The carrier substrate 136 may be attached by a bonding layer (not separately illustrated), which may be removed along with the carrier substrate 136 from the structure after processing. In some embodiments, the bonding layer includes an oxide, such as a layer of silicon oxide. In some embodiments, the bonding layer includes an adhesive, such as a suitable epoxy or the like. The wafer 110 may be flipped over (not separately illustrated) to prepare for processing of the back-side of the wafer 110.

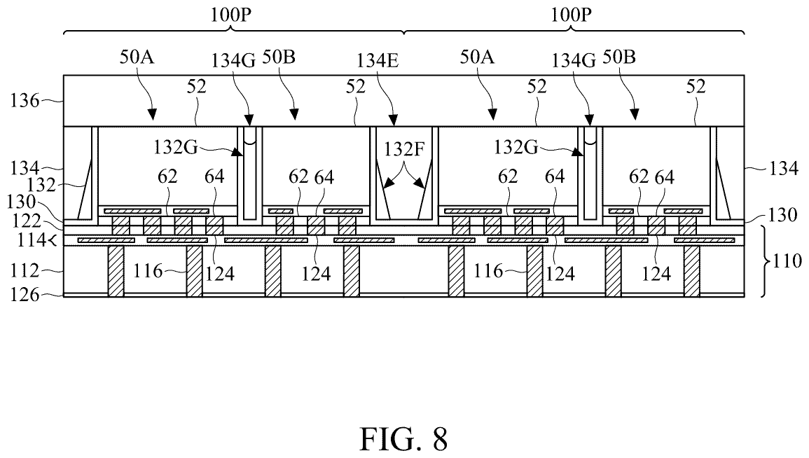

In FIG. 8, the substrate 112 is thinned to expose the conductive vias 116 at the back-side of the wafer 110. Exposure of the conductive vias 116 may be accomplished by a thinning process, such as a grinding process, a chemical-mechanical polish (CMP), an etch-back, combinations thereof, or the like. In the illustrated embodiment, a recessing process is performed to recess the inactive surface the substrate 112 such that the conductive vias 116 protrude at the back-side of the wafer 110. The recessing process may be, e.g., a suitable etch-back process, chemical-mechanical polish (CMP), or the like. In some embodiments, the thinning process for exposing the conductive vias 116 includes a CMP, and the conductive vias 116 protrude at the back-side of the wafer 110 as a result of dishing that occurs during the CMP. An insulating layer 126 is then formed on the inactive surface of the substrate 112, surrounding the protruding portions of the conductive vias 116. In some embodiments, the insulating layer 126 is formed of a silicon-containing insulator, such as silicon nitride, silicon oxide, silicon oxynitride, or the like, which may be formed by a suitable deposition method such as CVD, plasma-enhanced CVD (PECVD), high density plasma CVD (HDP-CVD), or the like. Initially, the insulating layer 126 may bury the conductive vias 116. A removal process can be applied to the various layers to remove excess materials over the conductive vias 116. The removal process may be a planarization process such as a chemical mechanical polish (CMP), an etch-back, combinations thereof, or the like. After planarization, the exposed surfaces of the conductive vias 116 and the insulating layer 126 are substantially coplanar (within process variations) and are exposed at the back-side of the wafer 110. In another embodiment, the insulating layer 126 is omitted, and the exposed surfaces of the substrate 112 and the conductive vias 116 are substantially coplanar (within process variations).

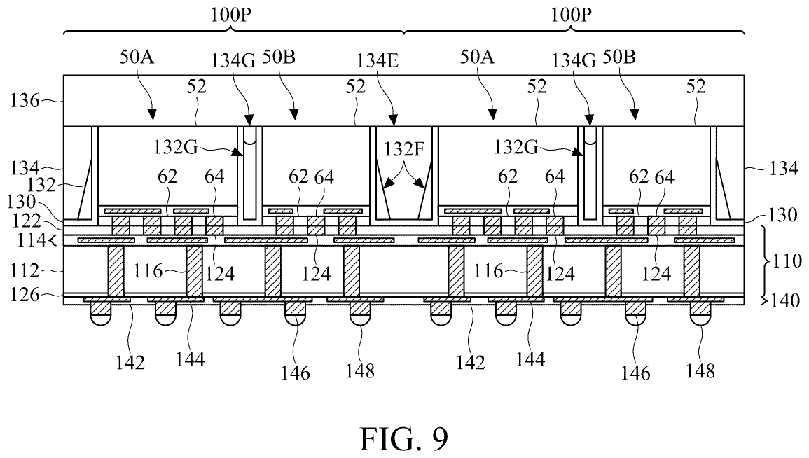

In FIG. 9, a redistribution structure 140 is formed on the back-side of the wafer 110. The redistribution structure 140 may be disposed on the bottom surface of the insulating layer 126 (if present) or the inactive surface of the substrate 112. The redistribution structure 140 includes one or more dielectric layer(s) 142 and respective metallization layer(s) 144 (sometimes referred to as redistribution layers or redistribution lines) among the dielectric layer(s) 142. The metallization layer(s) 144 of the redistribution structure 140 are connected to the conductive vias 116. Specifically, the metallization layer(s) 144 are connected to the integrated circuit dies 50 by the conductive vias 116 and the interconnect structure 114. The redistribution structure 140 is illustrated as an example, and may include more or fewer dielectric layer(s) 142 and metallization layer(s) 144 than illustrated.

The dielectric layer(s) 142 are formed of suitable dielectric material(s). In some embodiments, the dielectric layer(s) 142 are formed of a polymer, which may be a photosensitive material such as PBO, polyimide, a BCB-based polymer, or the like, which may be patterned using a lithography mask. In other embodiments, the dielectric layer(s) 142 are formed of an oxide such as silicon oxide, PSG, BSG, BPSG; a nitride such as silicon nitride; a combination thereof such as silicon oxynitride; or the like. The dielectric layer(s) 142 may be formed by spin coating, lamination, CVD, the like, or a combination thereof. After each dielectric layer 142 is formed, it is then patterned to expose underlying conductive features, e.g. underlying portions of the conductive vias 116 or the metallization layer(s) 144. The patterning may be by an acceptable process, such as by exposing the dielectric layer 142 to light when it is a photosensitive material, or by etching using, for example, an anisotropic etch. If the dielectric layer 142 is formed of a photosensitive material, it can be developed after the exposure.

The metallization layer(s) 144 each include conductive vias and/or conductive lines. The conductive vias extend through the dielectric layer(s) 142, and the conductive lines extend along the dielectric layer(s) 142. As an example to form a metallization layer 144, a seed layer (not separately illustrated) is formed over the respective underlying features. For example, the seed layer can be formed on a respective dielectric layer 142 and in the openings through the respective dielectric layer 142, or can be formed on the conductive vias 116 and the insulating layer 126 (if present) or the substrate 112. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using a deposition process, such as PVD or the like. A photoresist is then formed and patterned on the seed layer. The photoresist may be formed by spin coating or the like and may be exposed to light for patterning. The pattern of the photoresist corresponds to the metallization layer 144. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may include a metal or a metal alloy, such as copper, titanium, tungsten, aluminum, the like, or combinations thereof. Then, the photoresist and portions of the seed layer on which the conductive material are not formed are removed. The photoresist may be removed by an acceptable ashing or stripping process, such as using an oxygen plasma or the like. Once the photoresist is removed, exposed portions of the seed layer are removed, such as by an acceptable etching process, such as by wet or dry etching. The remaining portions of the seed layer and conductive material form the metallization layer 144.

When the substrate 112 is thinned, the redistribution structure 140 and the wafer 110 may have small combined thickness. In some embodiments, the combined thickness of the redistribution structure 140 and the wafer 110 is in the range of 50 μm to 80 μm, such as less than about 100 μm. The combined thickness of the redistribution structure 140 and the wafer 110 may be less than the thickness of the encapsulant 134.

Optionally, additional features may be formed for attaching the die structures 100 to package components. In some embodiments, under bump metallurgies (UBMs) 146 are formed for external connection to the redistribution structure 140. Further, conductive connectors 148 may be formed on the UBMs 146. The conductive connectors 148 may be used to connect the UBMs 146 to a package component such as an interposer, a package substrate, or the like.

The UBMs 146 may be formed through a lower dielectric layer 142 of the redistribution structure 140. The UBMs 146 have bump portions on and extending along the major surface of the lower dielectric layer 142, and have via portions extending through the lower dielectric layer 142 to physically and electrically couple the lower metallization layer 144 of the redistribution structure 140. As a result, the UBMs 146 are electrically coupled to the conductive vias 116 and the integrated circuit dies 50. The UBMs 146 may be formed of the same material(s) as the metallization layer(s) 144. In some embodiments, the UBMs 146 have a different size than the metallization layer(s) 144.

The conductive connectors 148 may be formed on the UBMs 146. The conductive connectors 148 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 148 may include a conductive material such as solder, copper, aluminum, gold, nickel, silver, palladium, tin, the like, or a combination thereof. In some embodiments, the conductive connectors 148 are formed by initially forming a layer of a reflowable material (e.g., solder) through evaporation, electroplating, printing, solder transfer, ball placement, or the like. Once a layer of solder has been formed on the structure, a reflow may be performed in order to shape the material into the desired bump shapes. In another embodiment, the conductive connectors 148 include metal pillars (such as copper pillars) formed by a sputtering, printing, electro plating, electroless plating, CVD, or the like. The metal pillars may be solder-free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof, which may be formed by a plating process.

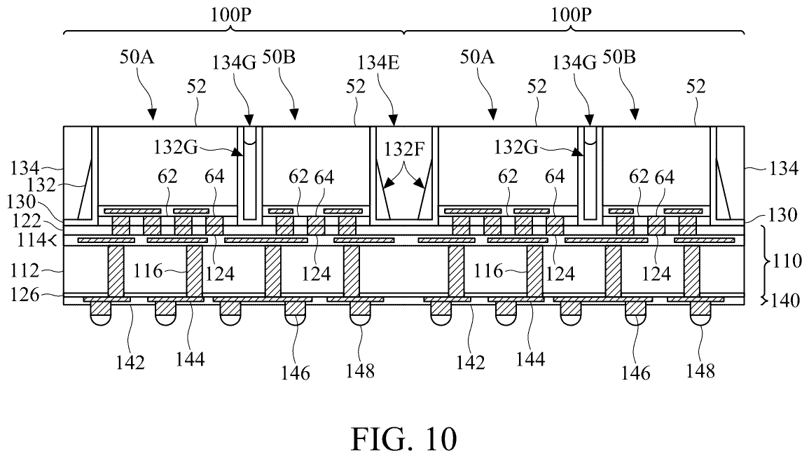

In FIG. 10, a carrier removal is performed to remove the carrier substrate 136 from the encapsulant 134. In embodiments where the carrier substrate 136 is attached to the encapsulant 134 by a bonding layer (e.g., an oxide layer or an adhesive), the removal process may include a grinding process applied to the carrier substrate 136 and the bonding layer. The structure is then flipped over and placed on a tape (not separately illustrated).

In FIG. 11, a singulation process is performed by cutting along scribe line regions, e.g., between the package regions 100P. The singulation process may include sawing, dicing, or the like. For example, the singulation process can include sawing the redistribution structure 140 (including the dielectric layer(s) 142); the wafer 110 (including the insulating layer 126 (if present), the substrate 112, the interconnect structure 114, and the dielectric layer 122); the liner layer 130 (if present); and the encapsulant 134. The singulation process singulates the package regions 100P from one another. The resulting, singulated die structure 100 is from one of the package regions 100P. The singulation process forms lower devices 150 from the singulated portions of the wafer 110. Each of the die structures 100 includes a lower device 150 and the integrated circuit dies 50 bonded thereto. As a result of the singulation process, the outer sidewalls of the lower device 150, the redistribution structure 140, the liner layer 130 (if present), and the encapsulant 134 are laterally coterminous (within process variations).

In this embodiment, the dies of the die structure 100 are directly bonded in a face-to-face manner, such that the front-sides of the integrated circuit dies 50 are bonded to the front-side of the lower device 150. Thus, the lower device 150 includes conductive vias 116, and the redistribution structure 140 is on the back-side of the lower device 150. In another embodiment (subsequently described for FIG. 14), the dies of the die structure 100 are directly bonded in a face-to-back manner, such that the front-sides of the integrated circuit dies 50 are bonded to the back-side of the lower device 150.

FIG. 12 is a cross-sectional view of a die structure 100, in accordance with some other embodiments. This embodiment is similar to the embodiment of FIG. 11, except the liner layer 130 is omitted and the buffer layer 132 is formed directly on the integrated circuit dies 50 and the lower device 150. Thus, the buffer layer 132 physically contacts the sidewalls of the integrated circuit dies 50 and the top surface of the lower device 150.

FIG. 13 is a cross-sectional view of a die structure 100, in accordance with some other embodiments. This embodiment is similar to the embodiment of FIG. 11, except the gap portions of the encapsulant 134 (between the integrated circuit dies 50) are removed by the removal process that is performed on the encapsulant 134 to expose the integrated circuit dies 50 (previously described for FIG. 6). The gap portions of the encapsulant 134 may fall out after manufacturing, so removing them may improve device reliability. When the gap portions of the encapsulant 134 are removed, the gap portion 132G of the buffer layer 132 is exposed through the encapsulant 134. It should be appreciated that the gap portions of the encapsulant 134 may also be removed from the embodiment of FIG. 12.

FIG. 14 is a cross-sectional view of a die structure 100, in accordance with some other embodiments. This embodiment is similar to the embodiment of FIG. 11, except the dies of the die structure 100 are directly bonded in a face-to-back manner, such that the front-sides of the integrated circuit dies 50 are bonded to the back-side of the lower device 150. The redistribution structure 140 and the insulating layer 126 are omitted; instead the dielectric layer 122 and the die connectors 124 are formed at the back-side of the lower device 150. The die connectors 124 may be physically and electrically coupled to the conductive vias 116. Further, the UBMs 146 may be formed through an upper dielectric layer of the interconnect structure 114 to physically and electrically couple an upper metallization layer of the interconnect structure 114. It should be appreciated that the dies of the die structure 100 may also be directly bonded in a face-to-back manner in the embodiments of FIGS. 12-13.

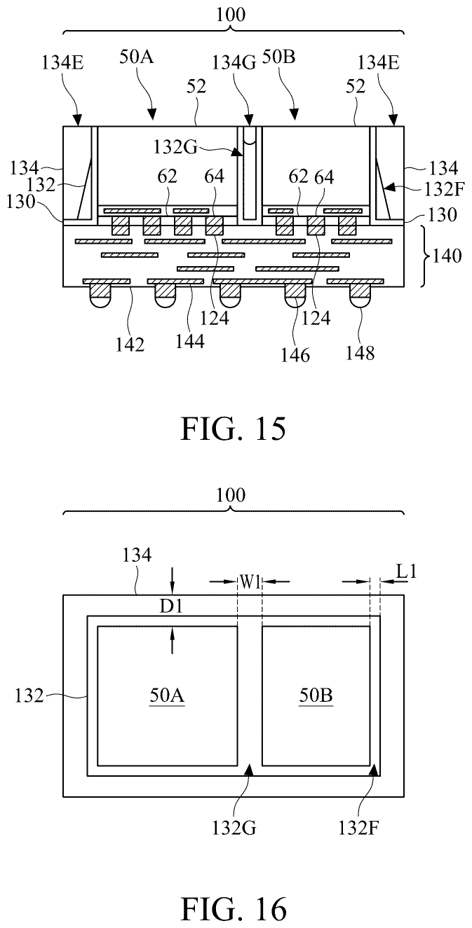

FIG. 15 is a cross-sectional view of a die structure 100, in accordance with some other embodiments. This embodiment is similar to the embodiment of FIG. 11, except the lower device 150 is omitted; instead, the integrated circuit dies 50 are bonded to the redistribution structure 140, which includes a large quantity of metallization layer(s) 144. In some embodiments, the redistribution structure 140 includes up to 8 metallization layers 144. The redistribution structure 140 may be built up on a carrier substrate, and may include die connectors 124 in an upper dielectric layer 142 of the redistribution structure 140. The integrated circuit dies 50 may be bonded to the die connectors 124 and to the upper dielectric layer 142. Appropriate steps as previously described may then be performed to complete formation of the die structure 100. Omitting the substrate 112 allows the thickness of the die structure 100 to be reduced. In some embodiments, the thickness of the each redistribution layer in the redistribution structure 140 is in the range of 6 μm to 8 μm, such as less than about 10 μm. It should be appreciated that the substrate 112 may also be omitted in the embodiments of FIGS. 12-13.

FIG. 16 is a planar view of a die structure 100, in accordance with some embodiments. A pattern of the buffer layer 132 in the planar view is illustrated, while some features have been omitted for illustration clarity. The buffer layers 132 of any of the die structures 100 of FIGS. 11-15 may have the illustrated pattern. The pattern of the buffer layer 132 may be selected to help reduce the risk of the integrated circuit dies 50 cracking. In this embodiment, the buffer layer 132 extends continuously around each of the integrated circuit dies 50 in the planar view.

The gap portion 132G of the buffer layer 132 has a width W1, measured between the integrated circuit dies 50. The fillet portion 132F of the buffer layer 132 has a length L1, measured from an edge of an integrated circuit die 50 to an edge of the buffer layer 132. In some embodiments, the width W1 is in the range of 40 μm to 100 μm, while the length L1 is in the range of 100 μm to 300 μm. Each of the integrated circuit dies 50 is disposed a distance D1 from the edges of the die structure 100 (e.g., from the edges of the encapsulant 134). The distance D1 is large, which provides space for dispensing the buffer layer 132. In some embodiments, the distance D1 is in the range of 300 μm to 500 μm, such as about 500 μm. As a result, the buffer layer 132 may not be sawed/cut during singulation of the die structure 100 (previously described for FIG. 11).

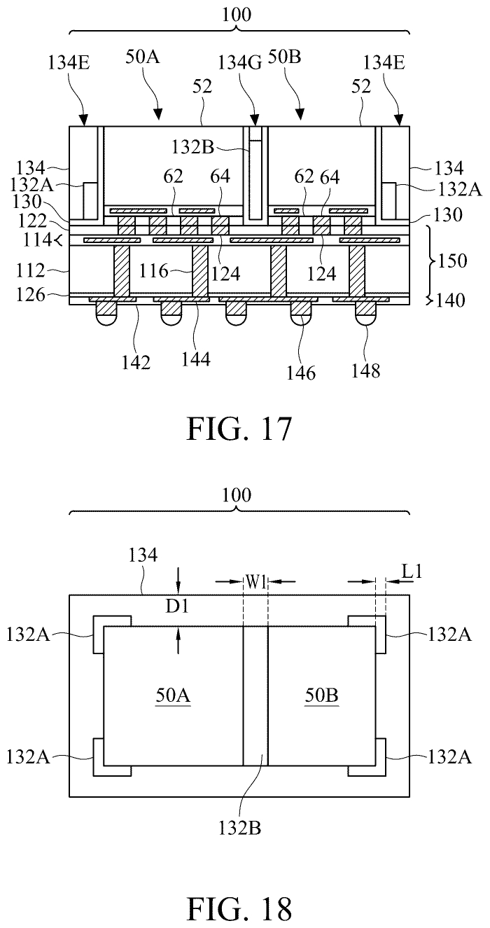

FIGS. 17 and 18 are views of a die structure 100, in accordance with some other embodiments. FIG. 17 is a cross-sectional view and FIG. 18 is a planar view. This embodiment is similar to the embodiment of FIGS. 11 and 16, except the die structure 100 includes a plurality of buffer layers 132 that extend discontinuously around the integrated circuit dies 50 in the planar view. The buffer layers 132 are selectively formed in desired locations, which may be selected to reduce manufacturing costs while still reducing the risk of the integrated circuit dies 50 cracking. It should be appreciated that a plurality of buffer layers 132 may also be used in the embodiments of FIGS. 12-15.

The buffer layers 132 may include outer buffer layers 132A and inner buffer layer(s) 132B. The outer buffer layers 132A are disposed along the outer edges of the integrated circuit dies 50, such as around the outer corners of the integrated circuit dies 50. The inner buffer layer(s) 132B are disposed in the gap(s) between the integrated circuit dies 50. In this embodiment, the outer buffer layers 132A lack fillets. In another embodiment (not separately illustrated), the outer buffer layers 132A include fillets. The outer buffer layers 132A may (or may not) have a different thickness than the inner buffer layer(s) 132B. For example, the inner buffer layer(s) 132B may have a greater thickness than the outer buffer layers 132A. In some embodiments, the outer buffer layers 132A have a thickness in the range of 100 μm to 200 μm, while the inner buffer layer(s) 132B have a thickness in the range of 150 μm to 400 μm.

The inner buffer layer(s) 132B have a width W1, which may (or may not) be similar to that previously described for FIG. 16. The outer buffer layers 132A have a length L1, which may (or may not) be similar to that previously described for FIG. 16. Each of the integrated circuit dies 50 is disposed a distance D1 from the edges of the die structure 100, which may (or may not) be similar to that previously described for FIG. 16.

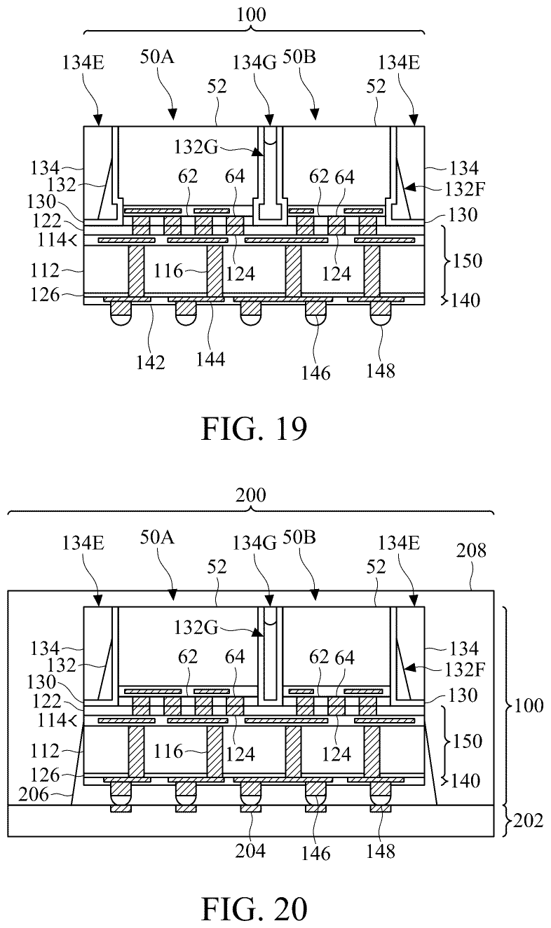

FIG. 19 is a cross-sectional view of a die structure 100, in accordance with some other embodiments. This embodiment is similar to the embodiment of FIG. 11, except the integrated circuit dies 50 include notches at their front-sides, such as notches in the semiconductor substrates 52, the interconnect structures 54 (see FIG. 1), and the dielectric layers 62. The liner layer 130 (if present) and/or the buffer layer 132 extend into the notches of the integrated circuit dies 50. It should be appreciated that the integrated circuit dies 50 may also include notches in the embodiments of FIGS. 12-18.

Generally, the previously described die structures 100 include a plurality of upper integrated circuit dies bonded to a lower substrate. The lower substrate may be a lower device 150 (e.g., an integrated circuit die, interposer, or the like) or may be a redistribution structure 140. In some embodiments where the lower device 150 is an integrated circuit die, the die structure 100 includes a plurality of upper integrated circuit dies bonded to a lower integrated circuit die. In some embodiments where the lower device 150 is an interposer, the die structure 100 includes a plurality of upper integrated circuit dies bonded to an interposer. In some embodiments where the lower device 150 is omitted, the die structure 100 includes a plurality of upper integrated circuit dies bonded to a redistribution structure. The buffer layer(s) 132 are around the upper integrated circuit dies.

The previously described die structures 100 are components that may be subsequently implemented in an integrated circuit package. The integrated circuit dies of a die structure 100 may be heterogeneous dies. Packaging the die structure 100 in lieu of or in addition to packaging dies individually may allow heterogeneous dies to be integrated with a small footprint. In some embodiments, an integrated circuit package is formed by encapsulating the die structure 100 and forming redistribution lines on the encapsulant to fan-out connections from the die structure 100. In some embodiments, an integrated circuit package is formed by attaching a die structure 100 to an additional component, such as an interposer, a package substrate, or the like.

FIG. 20 is a cross-sectional view of an integrated circuit package 200, in accordance with some embodiments. The integrated circuit package 200 includes a die structure 100 bonded to a package component 202. The package component 202 may be an interposer, a package substrate, or the like. Although the integrated circuit package 200 is illustrated as including the die structure 100 of FIG. 11, any of the die structures 100 described herein could be utilized.

In the illustrated embodiment, the die structure 100 is attached to the package component 202 with the conductive connectors 148. Die connectors 204 are at the front-side of the package component 202. The conductive connectors 148 are reflowed to attach the UBMs 146 of the die structure 100 to the die connectors 204 of the package component 202. The encapsulant 134 may expand during the reflowing process as a consequent of its large CTE. The buffer layer 132 reduces stress exerted on the bonding interfaces of the integrated circuit dies 50 and the wafer 110 by the encapsulant 134 during the reflowing process.

An underfill 206 may be formed around the conductive connectors 148, and between the package component 202 and the die structure 100. The underfill 206 may be formed by a capillary flow process after the die structure 100 is attached or may be formed by a suitable deposition method before the die structure 100 is attached. The underfill 206 may be a continuous material extending from the package component 202 to the die structure 100. The material of the underfill 206 is different from the stress reduction compound of the buffer layer 132, and may be formed by a different method than the stress reduction compound of the buffer layer 132.

An encapsulant 208 is formed on and around the various components. The encapsulant 208 encapsulates the die structure 100. The encapsulant 208 may be a molding compound, epoxy, or the like. The encapsulant 208 may be applied by compression molding, transfer molding, or the like. The encapsulant 208 may be applied in liquid or semi-liquid form and then subsequently cured.

Embodiments may achieve advantages. The encapsulant 134 has a large CTE as compared to that of the integrated circuit dies 50, such that there may be a CTE mismatch between the encapsulant 134 and the integrated circuit dies 50. The buffer layers 132 may reduce stress exerted on the bonding interfaces of the integrated circuit dies 50 and the wafer 110 as a result of CTE mismatch. Specifically, the buffer layers 132 are formed of a stress reduction compound, which has a CTE that is greater than the CTE of the semiconductor material of the integrated circuit dies 50, and is less than the CTE of the molding compound of the encapsulant 134. Thus, the buffer layers 132 may reduce the risk of the dielectric layers 62, 122 delaminating during expansion of the encapsulant 134 at high temperatures. The yield and reliability of the die structures 100 may thus be improved. In an experiment, the buffer layers 132 reduced stress exerted on the bonding interfaces of the integrated circuit dies 50 and the wafer 110 by about 32%.

In an embodiment, a device includes: a lower substrate; upper integrated circuit dies bonded to the lower substrate with dielectric-to-dielectric bonds and with metal-to-metal bonds, the upper integrated circuit dies including a semiconductor material; a buffer layer around the upper integrated circuit dies, the buffer layer including a stress reduction compound, a coefficient of thermal expansion of the stress reduction compound being greater than a coefficient of thermal expansion of the semiconductor material; and an encapsulant around the buffer layer and the upper integrated circuit dies, the encapsulant including a molding compound, a coefficient of thermal expansion of the molding compound being greater than the coefficient of thermal expansion of the stress reduction compound. In some embodiments of the device, the buffer layer physically contacts sidewalls of the upper integrated circuit dies. In some embodiments, the device further includes: a liner layer between the buffer layer and the upper integrated circuit dies. In some embodiments of the device, a gap portion of the buffer layer is between the upper integrated circuit dies, a gap portion of the encapsulant is between the upper integrated circuit dies, and the gap portion of the encapsulant is over the gap portion of the buffer layer. In some embodiments of the device, a gap portion of the buffer layer is between the upper integrated circuit dies, and the gap portion of the buffer layer is exposed through the encapsulant. In some embodiments of the device, front-sides of the upper integrated circuit dies are bonded to a front-side of the lower substrate. In some embodiments of the device, front-sides of the upper integrated circuit dies are bonded to a back-side of the lower substrate. In some embodiments of the device, the buffer layer extends continuously around each of the upper integrated circuit dies in a planar view. In some embodiments of the device, the buffer layer is one of a plurality of buffer layers that extend discontinuously around the upper integrated circuit dies in a planar view. In some embodiments of the device, the lower substrate is a lower integrated circuit die. In some embodiments of the device, the lower substrate is an interposer. In some embodiments of the device, the lower substrate is a redistribution structure.

In an embodiment, a device includes: a lower substrate; an upper integrated circuit die bonded to the lower substrate with dielectric-to-dielectric bonds and with metal-to-metal bonds; a liner layer on a sidewall of the upper integrated circuit die and a top surface of the lower substrate; a buffer layer on the liner layer; and an encapsulant around the buffer layer, a top surface of the encapsulant being coplanar with a top surface of the liner layer and a top surface of the upper integrated circuit die. In some embodiments of the device, the liner layer includes an oxide layer and a nitride layer on the oxide layer. In some embodiments of the device, the buffer layer includes a stress reduction compound, and the stress reduction compound includes a polymer material and a filler. In some embodiments of the device, the polymer material is a thermoplastic polymer and the filler is particles of silica.

In an embodiment, a method includes: bonding an upper integrated circuit die to a lower substrate with dielectric-to-dielectric bonds and with metal-to-metal bonds, the upper integrated circuit die having a first coefficient of thermal expansion; forming a stress reduction compound around the upper integrated circuit die, the stress reduction compound having a second coefficient of thermal expansion; forming a molding compound around the stress reduction compound, the molding compound having a third coefficient of thermal expansion, the second coefficient of thermal expansion being between the first coefficient of thermal expansion and the third coefficient of thermal expansion; and singulating the molding compound and the lower substrate. In some embodiments of the method, forming the stress reduction compound includes depositing the stress reduction compound with chemical vapor deposition. In some embodiments, the method further includes: depositing a liner layer on the upper integrated circuit die and the lower substrate, the stress reduction compound formed on the liner layer. In some embodiments, the method further includes: thinning the molding compound, a thickness of the molding compound being greater than a thickness of a fillet portion of the stress reduction compound, the fillet portion of the stress reduction compound disposed along an outer edge of the upper integrated circuit die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a first integrated circuit die comprising a first semiconductor substrate, a first dielectric layer over the first semiconductor substrate, first die connectors in the first dielectric layer, and conductive vias extending through the first semiconductor substrate;
a second integrated circuit die comprising a second semiconductor substrate, a second dielectric layer over the second semiconductor substrate, and second die connectors in the second dielectric layer, the second die connectors being metal-to-metal bonded to the first die connectors without solder, the second dielectric layer being dielectric-to-dielectric bonded to the first dielectric layer without adhesive, the second semiconductor substrate comprising a semiconductor material;
a buffer layer around the second integrated circuit die, the buffer layer comprising a stress reduction compound having a polymer material and a filler, a coefficient of thermal expansion of the stress reduction compound being greater than a coefficient of thermal expansion of the semiconductor material;
an encapsulant around the buffer layer and the second integrated circuit die, the encapsulant comprising a molding compound, a coefficient of thermal expansion of the molding compound being greater than the coefficient of thermal expansion of the stress reduction compound; and
a redistribution structure on the first integrated circuit die, the redistribution structure comprising dielectric layers, metallization layers among the dielectric layers, and under bump metallurgies coupled to a bottom one of the metallization layers, the conductive vias electrically coupling the metallization layers to the first die connectors.

2. The device of claim 1, wherein the buffer layer physically contacts sidewalls of the second integrated circuit die.

3. The device of claim 1, further comprising:
a liner layer between the buffer layer and the second integrated circuit die.

4. The device of claim 3, wherein the liner layer comprises an oxide layer and a nitride layer on the oxide layer.

5. The device of claim 1, wherein a first portion of the buffer layer extends along a first sidewall of the second integrated circuit die, a second portion of the buffer layer extends along a second sidewall of the second integrated circuit die, and the encapsulant is over both the first portion and the second portion of the buffer layer.

6. The device of claim 1, wherein a first portion of the buffer layer extends along a first sidewall of the second integrated circuit die, a second portion of the buffer layer extends along a second sidewall of the second integrated circuit die, the encapsulant is over the first portion of the buffer layer, and a top surface of the encapsulant is coplanar with a top surface of the second portion of the buffer layer.

7. The device of claim 1, wherein the first die connectors and the first dielectric layer are disposed at a front side of the first integrated circuit die.

8. The device of claim 1, wherein the first die connectors and the first dielectric layer are disposed at a back side of the first integrated circuit die.

9. A device comprising:
a lower substrate;
a plurality of upper integrated circuit dies bonded to the lower substrate, each of the upper integrated circuit dies comprising a semiconductor material having a first coefficient of thermal expansion;
a plurality of discontinuous buffer layers around the upper integrated circuit dies, each of the discontinuous buffer layers comprising a stress reduction compound having a second coefficient of thermal expansion, the discontinuous buffer layers comprising:
a plurality of outer buffer layers disposed along outer edges of the upper integrated circuit dies; and
a plurality of inner buffer layers disposed between the upper integrated circuit dies; and
an encapsulant around the discontinuous buffer layers, the encapsulant comprising a molding compound having a third coefficient of thermal expansion, the second coefficient of thermal expansion being between the first coefficient of thermal expansion and the third coefficient of thermal expansion.

10. The device of claim 9, wherein the outer buffer layers are disposed around outer corners of the upper integrated circuit dies.

11. The device of claim 9, wherein the stress reduction compound comprises a polymer material and a filler, the filler having a load in a range of 60% to 90%.

12. The device of claim 9, wherein the inner buffer layers have a greater thickness than the outer buffer layers.

13. The device of claim 9, wherein the upper integrated circuit dies include notches, and wherein at least a subset of the discontinuous buffer layers extend into the notches.

14. A device comprising:
a lower integrated circuit die;
an upper integrated circuit die bonded to the lower integrated circuit die;
a liner layer on a first sidewall of the upper integrated circuit die and a top surface of the lower integrated circuit die, the liner layer comprising an inorganic dielectric material;
a first buffer layer on the liner layer, the first buffer layer extending along the first sidewall of the upper integrated circuit die, the first buffer layer comprising a stress reduction compound; and
an encapsulant around the first buffer layer, a top surface of the encapsulant being coplanar with a top surface of the liner layer and a top surface of the upper integrated circuit die, the encapsulant comprising a molding compound, the stress reduction compound being different from the molding compound.

15. The device of claim 14, wherein the liner layer is also on a second sidewall of the upper integrated circuit die, and the first buffer layer also extends along the second sidewall of the upper integrated circuit die.

16. The device of claim 14, wherein the liner layer is also on a second sidewall of the upper integrated circuit die, and the device further comprises:
a second buffer layer on the liner layer, the second buffer layer extending along the second sidewall of the upper integrated circuit die, the second buffer layer being disconnected from the first buffer layer.

17. The device of claim 16, wherein the first buffer layer has a greater thickness than the second buffer layer.

18. The device of claim 14, wherein the inorganic dielectric material is a nitride or oxide.

19. The device of claim 14, wherein the stress reduction compound comprises a thermoplastic polymer material and particles of silica.

20. The device of claim 14, wherein the upper integrated circuit die comprises a semiconductor material, a coefficient of thermal expansion of the stress reduction compound being between a coefficient of thermal expansion of the molding compound and a coefficient of thermal expansion of the semiconductor material.
